(19) United States
(12) Patent Application Publication
(10) Pub. No.: US 2023/0162975 A1
(43) Pub. Date: May 25, 2023

(54) MANUFACTURING METHOD OF NITRIDE SEMICONDUCTOR STRUCTURE

(71) Applicant: HannStar Display Corporation, Taipei City (TW)

(72) Inventors: Yu-Chi Chiao, Taipei City (TW); Yung-Li Huang, Tainan City (TW); Chun I Chu, Hsinchu County (TW); Sheng Wei Chou, New Taipei City (TW)

(73) Assignee: HannStar Display Corporation, Taipei City (TW)

(21) Appl. No.: 17/970,610

(22) Filed: Oct. 21, 2022

(30) Foreign Application Priority Data
Nov. 22, 2021 (CN) 202111386359.3

(51) Int. Cl. H01L 21/02

(52) U.S. Cl. CPC H01L 21/02458; H01L 21/0254

(57) ABSTRACT

The disclosure provides a manufacturing method of a nitride semiconductor structure. The method includes the followings. Multiple island structures separated from each other are formed on a sapphire substrate. A GaN layer is formed on the island structures. A silicon substrate is bonded to a surface of the GaN layer facing away from the sapphire substrate. The sapphire substrate, the island structures, and a first sublayer of the GaN layer are removed. The first sublayer of the GaN layer has multiple voids, and the voids are located between the island structures.

### CROSS-REFERENCE TO RELATED APPLICATION

This application claims the priority benefit of Chinese application serial no. 202111386359.3, filed on Nov. 22, 2021. The entirety of the above-mentioned patent application is hereby incorporated by reference herein and made a part of this specification.

### BACKGROUND

### Technical Field

The disclosure relates to a manufacturing method of a semiconductor structure, in particular to a manufacturing method of a nitride semiconductor structure.

### Description of Related Art

GaN semiconductors are suitable for the production of high power or high frequency electronic components because of their wide energy void. Due to the advantages of high thermal conductivity, high electrical conductivity, easy cutting and low cost, the production of GaN semiconductor components on silicon substrates has become the focus of development for related manufacturers. However, the lattice constants and thermal expansion coefficients of GaN semiconductor structures are different from those of silicon substrates. As a result, the nitride semiconductor structure formed on the silicon substrate is prone to a large number of dislocation defects, resulting in the nitride semiconductor structure being prone to fracture. In addition, the silicon substrate and the nitride semiconductor structure are prone to warpage during the cooling down process, which affects the process yield of subsequent chips.

### SUMMARY

The disclosure is directed to a manufacturing method of a nitride semiconductor structure. The manufacturing method enables a formation of a nitride semiconductor structure with low defect density on a silicon substrate.

According to an embodiment of the disclosure, a manufacturing method of a nitride semiconductor structure includes the followings. Multiple island structures separated from each other are formed on a sapphire substrate. A GaN layer is formed on the island structures. A silicon substrate is bonded to a side of the GaN layer facing away from the sapphire substrate. The sapphire substrate, the island structures, and a first sublayer of the GaN layer are removed. The first sublayer of the GaN layer has multiple voids, and the voids are located between the island structures.

In the manufacturing method of a nitride semiconductor structure according to an embodiment of the disclosure, a SiNx layer is formed on a surface of the sapphire substrate before the island structures are formed. The SiNx layer has multiple openings. The island structures are disposed corresponding to the openings, and the voids do not overlap the openings of the SiNx layer.

According to an embodiment of the disclosure, the manufacturing method of the nitride semiconductor structure further includes that the SiNx layer is removed.

In the manufacturing method of a nitride semiconductor structure according to an embodiment of the disclosure, the voids and the SiNx layer have a height of less than 0.5 μm along a normal direction of the surface of the sapphire substrate.

In the manufacturing method of a nitride semiconductor structure according to an embodiment of the disclosure, a bonding process of the silicon substrate and the GaN layer includes the followings. A first bonding layer is formed on the GaN layer. A second bonding layer is formed on the silicon substrate. A heat treatment is performed to weld the first bonding layer and the second bonding layer.

In the manufacturing method of a nitride semiconductor structure according to an embodiment of the disclosure, a material of the first bonding layer and the second bonding layer includes silicon dioxide.

In the manufacturing method of a nitride semiconductor structure according to an embodiment of the disclosure, after the removal of the island structures and the first sublayer of the GaN layer is completed, a defect density of the GaN layer is less than 1×10⁸ cm⁻².

In the manufacturing method of a nitride semiconductor structure according to an embodiment of the disclosure, a difference in lattice constants between the sapphire substrate and the GaN layer is less than a difference in lattice constants between the silicon substrate and the GaN layer.

In the manufacturing method of a nitride semiconductor structure according to an embodiment of the disclosure, the GaN layer further has a second sublayer. The first sublayer is disposed between the second sublayer and the sapphire substrate, and is located between the island structures. A defect density of the first sublayer is greater than a defect density of the second sublayer.

In the manufacturing method of a nitride semiconductor structure according to an embodiment of the disclosure, the island structures are of the same material as the GaN layer.

Based on the above, in the manufacturing method of a nitride semiconductor structure according to an embodiment of the disclosure, before the GaN layer is formed, the island structures separated from each other are first formed on the sapphire substrate. The island structures may allow a dislocation defect of a subsequently growing GaN layer to be concentrated in the voids between the island structures. Accordingly, the defect density of the GaN layer may be effectively reduced. In addition, after the silicon substrate is bonded to a side surface of the GaN layer away from the island structures, the island structures and the first sublayer of the GaN layer are removed to form a high-quality GaN layer on the silicon substrate, which helps to improve the electrical operability and reliability of the nitride semiconductor structure on the silicon substrate.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic cross-sectional view of a nitride semiconductor structure according to an embodiment of the disclosure.

FIG. 2A to FIG. 2F are schematic cross-sectional views of a process of a manufacturing method of the nitride semiconductor structure of FIG. 1.

### DESCRIPTION OF THE EMBODIMENTS

Reference will now be made in detail to the exemplary embodiments of the disclosure, and examples of the exemplary embodiments are illustrated in the accompanying drawings. Whenever possible, the same numeral references are used in the drawings and descriptions to indicate the same or similar parts.

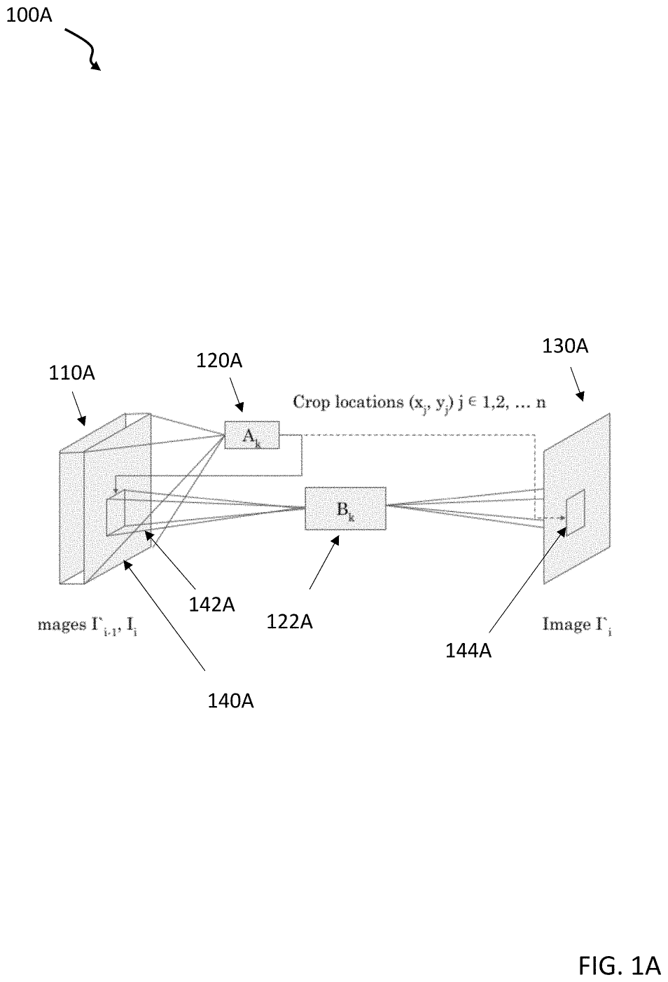

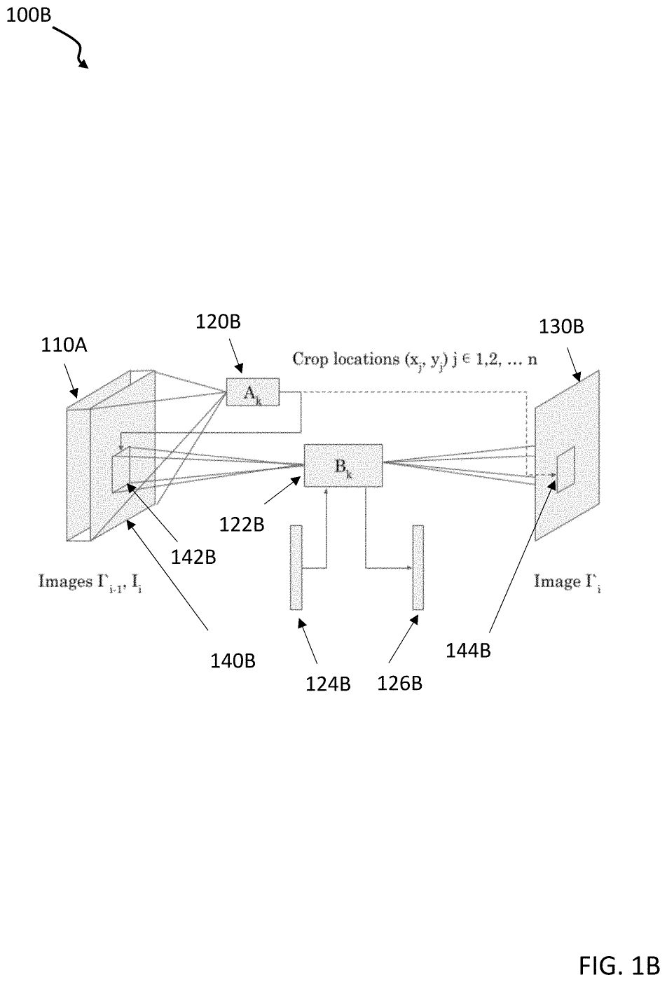

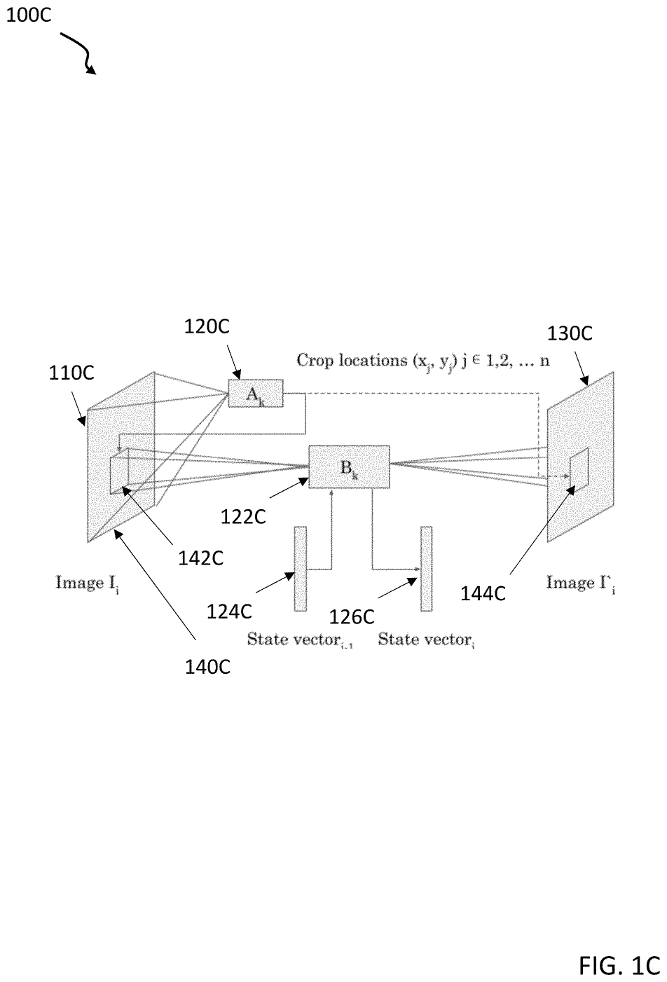

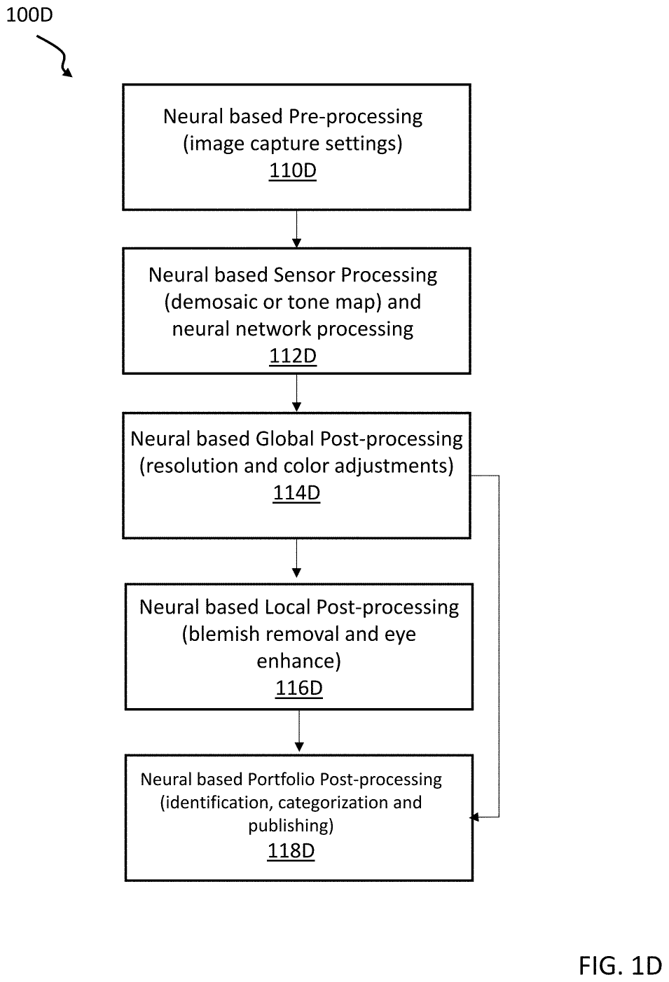

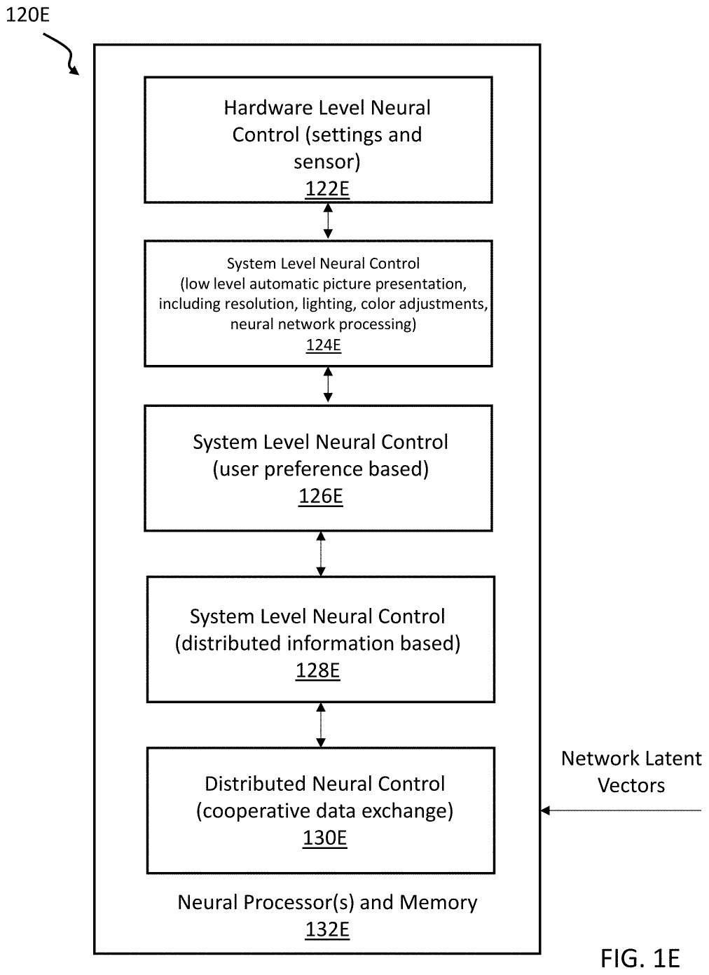

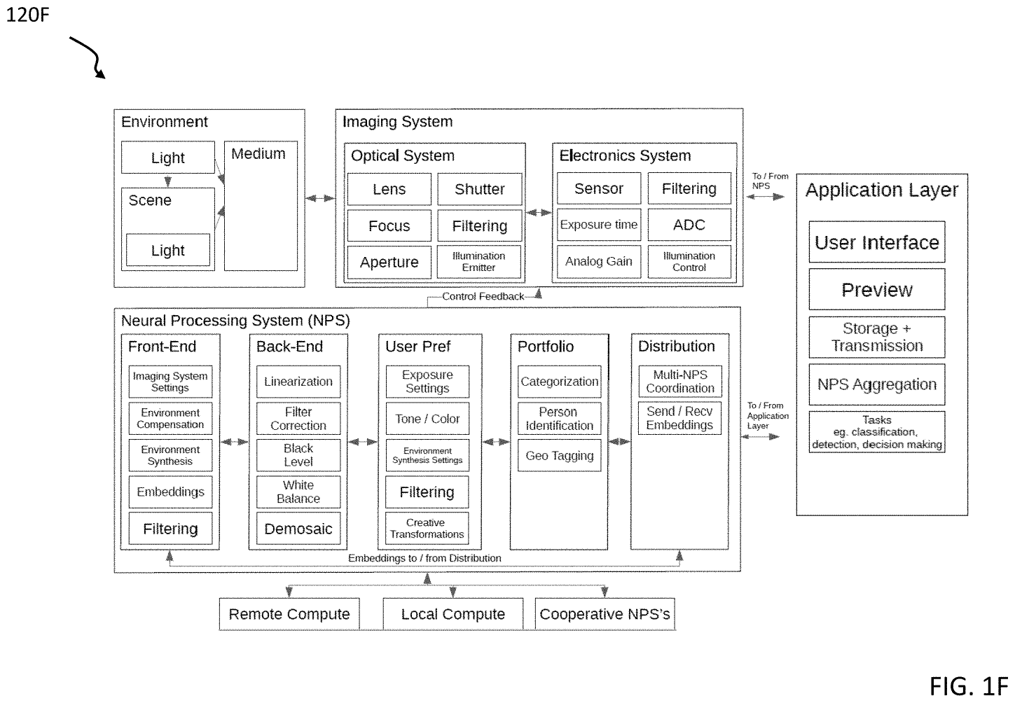

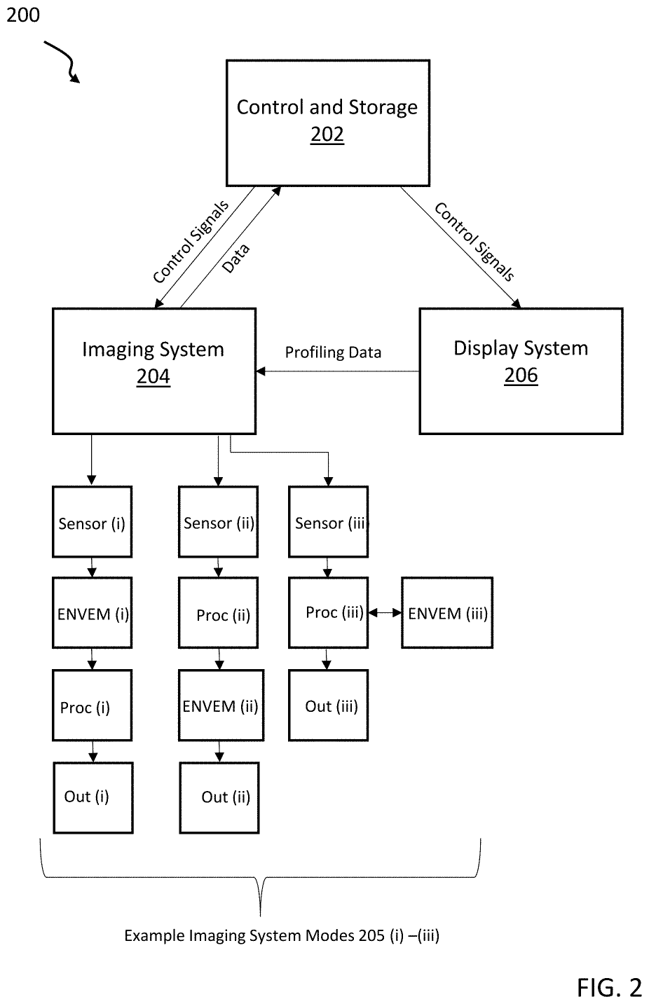

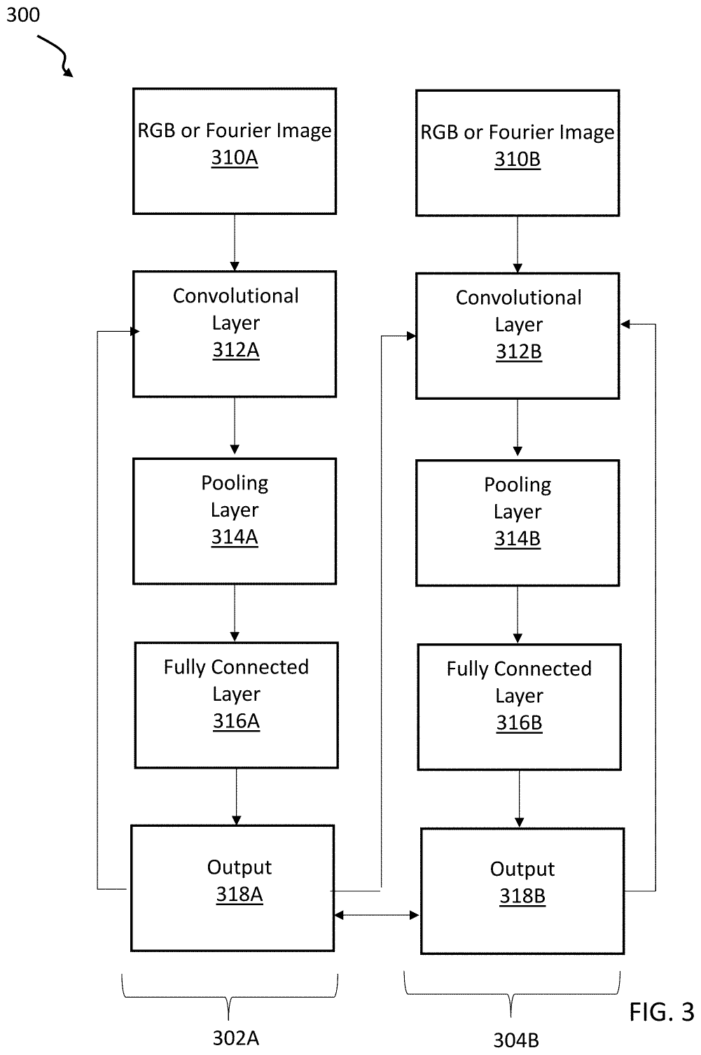

FIG. 1 is a schematic cross-sectional view of a nitride semiconductor structure according to an embodiment of the disclosure. FIG. 2A to FIG. 2F are schematic cross-sectional views of a process of a manufacturing method of the nitride semiconductor structure of FIG. 1. Referring to FIG. 1, a nitride semiconductor substrate 10 includes a silicon substrate 200 and a nitride semiconductor structure NSS disposed on the silicon substrate 200. According to this embodiment, the nitride semiconductor structure NSS is bonded to the silicon substrate 200 through the connection between a first bonding layer 181 and a second bonding layer 182. The silicon substrate 200 is, for example, a silicon wafer with a lattice orientation of (1 1 1) or (1 0 0) or other suitable silicon-based wafers.

It should be noted that the nitride semiconductor structure NSS includes, for example, a GaN layer with a dislocation defect density of less than 1×10⁸ cm⁻². More specifically, unlike the general nitride semiconductor structure using a silicon substrate, the silicon substrate 200 of the nitride semiconductor substrate 10 disclosed in this disclosure may be provided with a better quality nitride semiconductor, which helps to improve the electrical operability and reliability of high power or high frequency electronic components made from the nitride semiconductor structure NSS on the silicon substrate 200.

The following is an exemplary description of the manufacturing method of the nitride semiconductor substrate 10.

Referring to FIG. 2A and FIG. 2B, a sapphire substrate 100 is provided, and multiple island structures 140 separated from each other are formed on the sapphire substrate 100. For example, before the island structures 140 are formed, a SiNx layer 120 may be formed on a surface 100s of the sapphire substrate 100. The SiNx layer 120 has multiple openings 120a, and the island structures 140 are disposed corresponding to the openings 120a. According to this embodiment, a material of the island structures 140 is, for example, gallium nitride (GaN). It should be noted that GaN cannot grow on the SiNx layer 120 and can only grow on the surface of the sapphire substrate 100 exposed by the openings 120a of the SiNx layer 120. During a growth process, a process temperature and air pressure of a reaction gas are adjusted to form the island structures 140. However, the disclosure is not limited thereto. According to other embodiments, the island structures 140 may also be manufactured in other ways (e.g., a photolithography and etching process) without first forming the SiNx layer 120 according to this embodiment on the sapphire substrate 100.

Referring to FIG. 2C, a GaN layer 160 is formed on the island structures 140. The material of the island structures 140 and the GaN layer 160 are optionally the same. According to this embodiment, the GaN layer 160 includes a first sublayer 161 and a second sublayer 162. The first sublayer 161 is disposed between the second sublayer 162 and the sapphire substrate 100, and is located between the island structures 140. It should be noted that the first sublayer 161 of the GaN layer 160 has multiple voids G. The voids G are located between the island structures 140 and do not overlap the openings 120a of the SiNx layer 120.

During a growth process of the first sublayer 161, a direction of the dislocation defect generated from a bottom layer may be redirected (e.g., from a direction substantially perpendicular to the sapphire substrate 100 to a direction substantially parallel to the sapphire substrate 100) by changing a V/III ratio and the air pressure of the reaction gas, and concentrated on the voids G. In other words, most of the dislocation defect may be confined in the first sublayer 161. Therefore, the defect density of the second sublayer 162 grown subsequently may be greatly reduced, e.g., the defect density of the second sublayer 162 may be less than 1×10⁸ cm⁻², i.e., the defect density of the first sublayer 161 of GaN layer 160 is greater than the defect density of the second sublayer 162. According to this embodiment, a height H of overlapped voids G and the SiNx layer 120 along a normal direction of the surface 100s of the sapphire substrate 100 may be less than 0.5 μm.

Referring to FIG. 2D and FIG. 2E, then, the silicon substrate 200 is bonded to a side of the GaN layer 160 facing away from the sapphire substrate 100. A difference in lattice constants between the sapphire substrate 100 and the GaN layer 160 is less than a difference in lattice constants between the silicon substrate 200 and the GaN layer 160. According to this embodiment, a bonding process of the silicon substrate 200 and the GaN layer 160 may include the followings. A first bonding layer 181 and a second bonding layer 182 are respectively formed on the GaN layer 160 and the silicon substrate 200. A material of the bonding layers is, for example, silicon dioxide, but not limited thereto. After the bonding layers are formed, wafer-to-wafer bonding technique is used to bond the silicon substrate 200 covered with the bonding layer to the GaN layer 160 (as shown in FIG. 2E).

For example, after the second bonding layer 182 on the silicon substrate 200 contacts the first bonding layer 181 on the GaN layer 160, a heat treatment is performed to weld the first bonding layer 181 and the second bonding layer 182. The heat treatment here is, for example, thermal annealing at a high temperature (e.g. 600 to 1200 degrees Celsius, depending on the type of bonding material) for several hours, so that a weak bond formed between the two bonding layers in contact is converted into a covalent bond, resulting in a strong and robust bond.

After the bonding of the silicon substrate 200 and the GaN layer 160 is completed, the sapphire substrate 100 is removed, as shown in FIG. 2F. For example, laser lift-off (LLO) technique may be used to detach the sapphire substrate 100 from the SiNx layer 120 and the island structures 140, thus completing a transfer step of the GaN layer 160 grown on the sapphire substrate 100.

Next, the SiNx layer 120, the island structures 140, and the first sublayer 161 of the GaN layer 160 are removed. For example, the SiNx layer 120 may be removed by the photolithography and etching process, where the etchant chosen should have a high etch selectivity for silicon nitride and gallium nitride, but not limited thereto. According to other embodiments, chemical-mechanical planarization (CMP) technique may also be used to remove the SiNx layer 120.

On the other hand, preferably, the CMP polishing technique may be used to remove the island structures 140 and the first sublayer 161. However, the disclosure is not limited thereto. According to other embodiments, the mechanical polishing technique or other suitable chip thinning techniques may also be used to perform the removal of the island structures 140 and the first sublayer 161. After removing the first sublayer 161, which has a large number of dislocation defects, the second sublayer 162 of the GaN layer 160 becomes a high-quality nitride semiconductor structure NSS on the silicon substrate 200, for example, a GaN layer with a defect density of less than 1×10⁸ cm⁻². Here, the manufacture of the nitride semiconductor substrate 10 of FIG. 1 is completed.

In summary, in the manufacturing method of a nitride semiconductor structure according to an embodiment of the disclosure, before the GaN layer is formed, the island structures separated from each other are first formed on the sapphire substrate. The island structures may allow a dislocation defect of a subsequently growing GaN layer to be concentrated in the voids between the island structures. Accordingly, the defect density of the GaN layer may be effectively reduced. In addition, after the silicon substrate is bonded to a side surface of the GaN layer away from the island structures, the island structures and the first sublayer of the GaN layer are removed to form a high-quality GaN layer on the silicon substrate, which helps to improve the electrical operability and reliability of the nitride semiconductor structure on the silicon substrate.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A manufacturing method of a nitride semiconductor structure comprising:
forming a plurality of island structures separated from each other on a sapphire substrate;
forming a GaN layer on the island structures, wherein a first sublayer of the GaN layer has a plurality of voids, and the voids are located between the island structures;
bonding a silicon substrate to a side of the GaN layer facing away from the sapphire substrate;
removing the sapphire substrate; and
removing the island structures and the first sublayer of the GaN layer.

2. The manufacturing method of the nitride semiconductor structure according to claim 1, wherein a SiNx layer is formed on a surface of the sapphire substrate before the island structures are formed, and the SiNx layer has a plurality of openings, wherein the island structures are disposed corresponding to the openings, and the voids do not overlap the openings of the SiNx layer.

3. The manufacturing method of the nitride semiconductor structure according to claim 2 further comprising: removing the SiNx layer.

4. The manufacturing method of the nitride semiconductor structure according to claim 2, wherein the voids and the SiNx layer have a height of less than 0.5 μm along a normal direction of the surface of the sapphire substrate.

5. The manufacturing method of the nitride semiconductor structure according to claim 1, wherein a bonding process of the silicon substrate and the GaN layer comprises:
forming a first bonding layer on the GaN layer;
forming a second bonding layer on the silicon substrate; and
performing a heat treatment to weld the first bonding layer and the second bonding layer.

6. The manufacturing method of the nitride semiconductor structure according to claim 5, wherein a material of the first bonding layer and the second bonding layer comprises silicon dioxide.

7. The manufacturing method of the nitride semiconductor structure according to claim 1, wherein after the removal of the island structures and the first sublayer of the GaN layer is completed, a defect density of the GaN layer is less than 1×10⁸ cm⁻².

8. The manufacturing method of the nitride semiconductor structure according to claim 1, wherein a difference in lattice constants between the sapphire substrate and the GaN layer is less than a difference in lattice constants between the silicon substrate and the GaN layer.

9. The manufacturing method of the nitride semiconductor structure according to claim 1, wherein the GaN layer further has a second sublayer, and the first sublayer is disposed between the second sublayer and the sapphire substrate and located between the island structures, wherein a defect density of the first sublayer is greater than a defect density of the second sublayer.

10. The manufacturing method of the nitride semiconductor structure according to claim 1, wherein the island structures are of the same material as the GaN layer.
